(19) United States
(12) Patent Application Publication
(10) Pub. No.: US 2015/0153488 A1
(43) Pub. Date: Jun. 4, 2015

(54) DISPLAY SUBSTRATE, DISPLAY DEVICE COMPRISING THE SAME AND METHOD FOR MANUFACTURING THE DISPLAY SUBSTRATE

(71) Applicant: BOE TECHNOLOGY GROUP CO., LTD., Beijing (CN)

(72) Inventors: Wenlin Zhang, Beijing (CN); Weifeng Zhou, Beijing (CN)

(73) Assignee: BOE TECHNOLOGY GROUP CO., LTD., Beijing (CN)

(21) Appl. No.: 14/366,309

(22) PCT Filed: Oct. 18, 2013
(86) PCT No.: PCT/CN2013/085490

§ 371 Date: Jun. 18, 2014

(30) Foreign Application Priority Data
Apr. 24, 2013 (CN) 201310146136.9

(51) Int. Cl. G02B 5/20; H01L 27/32; H01L 51/52; G02F 1/1335

(52) U.S. Cl. CPC G02B 5/201; G02F 1/133512; G02F 1/133516; H01L 27/322; H01L 51/5284; G02F 2001/133357

(57) ABSTRACT

Embodiments of the disclosure disclose a display substrate, a display device comprising the display substrate and a method for manufacturing the display substrate. The display substrate comprising a base substrate (1), a black matrix (2) and a color filter (3) formed on the base substrate (1), the color filter (3) and the black matrix (2) are arranged alternately with a height difference existing between the black matrix (2) and the color filter (3). The display substrate further comprises a planarizing layer (40) formed on the black matrix (2) or on both the black matrix (2)and the color filter (3). The planarizing layer (40) is configured to minimize the height difference between the black matrix (2) and the color filter (3). Thus, the height difference between the black matrix (2) and the color filter (3) can be minimized, and surface smoothness of the color filter (3) is improved effectively. Therefore, image displaying quality is improved.

### FIELD

Embodiments of the present disclosure relate to a display substrate, a display device and a method for manufacturing the display substrate.

### BACKGROUND

With a decrease of manufacturing cost and improvement of manufacturing process of a display panel, the application of the display panel becomes wider.

The display panel generally consists of a display substrate. The display substrate generally at least comprises a base substrate 1, a black matrix formed on the base substrate 1, and color filter 3 formed on the base substrate 1 and disposed in pixel regions defined by the black matrix 2. The color filter 3 normally comprises a red resin layer, a green resin layer and a blue resin layer. The color filter 3 and the black matrix 2 are arranged alternately, as illustrated in FIG. 1.

In a manufacturing method of a conventional display substrate, at first, patterns of a black matrix 2 is formed on a surface of a base substrate 1, and then a red resin layer, a green resin layer and a blue resin layer are deposited in sequence, hence a color filter 3 is finally formed. However, in the manufacturing processes, it is hard to control a height of the color filter 3 to be equal to a height of the black matrix. Normally, the color filter 3 is made higher than the black matrix 2 and a height difference is produced between the color filter 3 and the black matrix 2, such that a surface of the color filter 3 is not smooth, as illustrated in FIG. 1.

The surface smoothness of the display substrate is very important to image displaying quality. The height difference between the black matrix 2 and the color filter 3 would be higher if other films were deposited on the black matrix 2 and the color filter 3, such that the surface of the display substrate is not smooth and product yield decreases. And further, in the successive processes, when rubbing an alignment layer, non-uniform rubbing occurs at the regions with the height difference such that the display device has a poor display quality.

### SUMMARY

One of objects of embodiments of the present disclosure is to provide a display substrate so as to solve a technical problem introduced by a color filter with an unsmooth surface which leads to product yield decrease and low display quality.

The above-mentioned object of embodiments of the disclosure is achieved by the following technical solution.

In one aspect, embodiments of the disclosure provide a display substrate comprising a base substrate, a black matrix and a color filter fowled on the base substrate. The color filter and the black matrix are arranged alternately with a height difference between the black matrix and the color filter. The display substrate further comprising a planarizing layer disposed on the black matrix or on both the black matrix and the color filter, and configured to planarize the height difference between the black matrix and the color filter.

In another aspect, embodiments of the disclosure provide a display device comprising the display substrate mentioned above.

In still another aspect, embodiments of the disclosure provide a method of manufacturing a display substrate. The method comprises: forming a black matrix and a color filter alternately on a base substrate; forming a planarizing layer on the base substrate on which the black matrix and the color filter are formed. The planarizing layer is configured to minimize a height difference between the black matrix and the color filter.

In the display substrate according to embodiments of the disclosure, the display device comprising the display substrate, and the display substrate manufactured by the method for manufacturing a display substrate according to embodiments of the disclosure, a planarizing layer is formed on the black matrix or on both the black matrix and the color filter so as to minimize the height difference between the black matrix and the color filter. Methods according to embodiments of the disclosure effectively improve surface smoothness of the color filter, increase product yield and improve the display quality.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a schematic view of a conventional display substrate;

FIG. 2 is a schematic view of a display substrate according to an embodiment of the disclosure;

FIG. 3 is a schematic view of another display substrate according to an embodiment of the disclosure; and

FIG. 4 is a schematic view of still another display substrate according to an embodiment of the disclosure.

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

Embodiments of the disclosure provide a display substrate. A planarizing layer is formed on the black matrix or on both the black matrix and the color filter so as to planarize a height difference between the black matrix and the color filter. Such planarizing layer minimizes the height difference between the black matrix and the color filter, and effectively improves surface smoothness of the color filter.

### First Embodiment

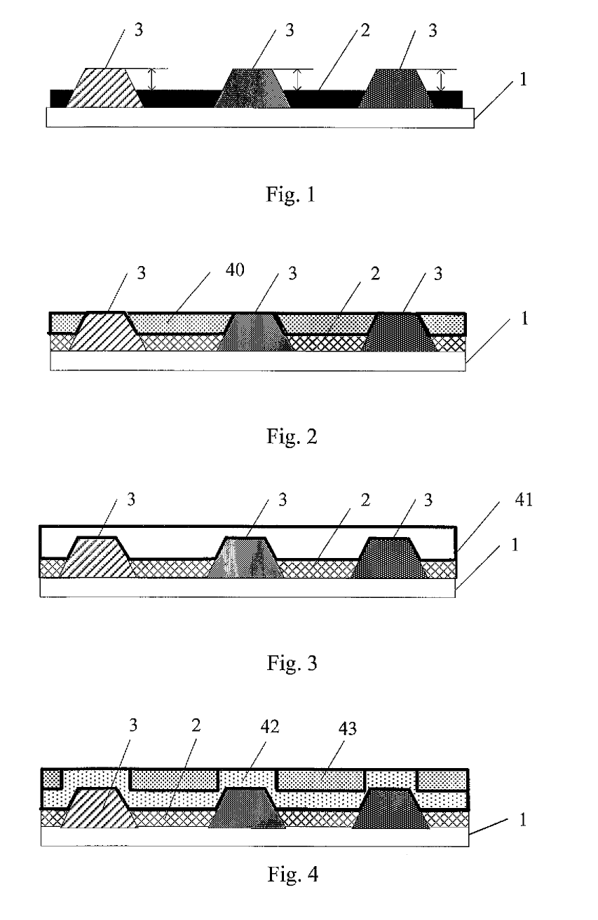

As illustrated in FIG. 1, a display substrate according to a first embodiment of the disclosure comprises a base substrate 1, a black matrix 2 formed on the base substrate 1, and a color filter 3 formed on the base substrate 1. The black matrix and the color filter have a height difference. The display substrate further comprises a planarizing layer disposed on the black matrix 2 or on both the black matrix 2 and the color filter 3, so as to planarize the height difference between the black matrix and the color filter 3.

Further, the planarizing layer in the first embodiment of the disclosure for planarizing the height difference between the black matrix and the color filter 3 can be made of a photoresist, for example. The planarizing layer can be formed by a simple lithography process, thus simplifying the manufacturing process.

In the embodiment, in case that the planarizing layer is made of the photoresist, the display substrate has a structure illustrated in FIG. 2. The display substrate according to the embodiment of the disclosure comprises a base substrate 1, a black matrix 2 formed on the base substrate 1, and the color filter 3 formed on the base substrate 1 and having a height difference with respect to the black matrix 2. A planarizing layer 40 is disposed on the black matrix 2, and an upper surface of the planarizing layer 40 is flushed with an upper surface of the color filter 3.

The photoresist comprises transparent photoresist and opaque photoresist. As the planarizing layer is disposed on the black matrix 2 in the embodiment, transmissivity of the planarizing layer will not affect transmissivity of the display substrate. Thus, the photoresist 40 for the planarizing layer in the embodiment can adopt transparent photoresist, and can also adopt opaque photoresist.

In the display substrate according to the embodiment, a planarizing layer made of photoresist is formed on the black matrix and the upper surface of the planarizing layer is flushed with the upper surface of the color filter. Thus, the height difference between the black matrix and the color filter can be minimized, and further, the surface smoothness of the color filter can be improved effectively.

It is conceivable by those skilled in the art that the photoresist can be replaced by a transparent resin in the embodiment so as to achieve the same object mentioned above.

### Second Embodiment

In the second embodiment of the disclosure, a transparent photoresist is used to make the planarizing layer in the display substrate, and the transparent photoresist is disposed on both the color filter and the black matrix. FIG. 3 is a schematic view of a display substrate according to the embodiment. The display substrate comprises a base substrate 1, a black matrix 2 formed on the base substrate 1, a color filter 3 formed on the base substrate 1 and having a height difference with respect to the black matrix 2. The display substrate further comprises a planarizing layer 41 disposed on both the black matrix 2 and the color filter 3. An upper surface of the planarizing layer 41 is a plane, that is to say, a portion of the planarizing layer 41 corresponding to the black matrix 2 and a portion of the planarizing layer 41 corresponding to the color filter 3 have different layer thickness. Thus, the height difference between the black matrix 2 and the color filter 3 is minimized. The planarizing layer 41 is made of a transparent photoresist.

In the display substrate according to the embodiment, the planarizing layer made of transparent photoresist is formed on both the black matrix and the color filter, and an upper surface of the planarizing layer is a plane. The transparent planarizing layer minimizes the height difference between the black matrix and the color filter and improves the surface smoothness of the color filter without affecting the transmissivity of the display substrate.

It should be understood that in the embodiment, the planarizing layer can be made of a transparent resin instead of the photoresist, and can also achieve the object mentioned above.

### Third Embodiment

As illustrated in FIG. 4, in the display substrate according to the third embodiment of the disclosure, the planarizing layer consists of a transparent resin portion 42 and a photoresist portion 43. The transparent resin portion 42 covers the black matrix 2 and the color filter 3, the photoresist portion 43 covers the portion of transparent resin corresponding to the region of the black matrix 2. An upper surface of the photoresist portion 43 is flushed with an upper surface of the portion transparent resin portion 42 corresponding to the color filter.

It should be understood that the transparent resin 42 in the embodiment can be made of a transparent organic resin material, a transparent inorganic resin material or any other materials capable of achieving the objects of the disclosure.

The planarizing layer according to the embodiment comprises a transparent resin portion and a photoresist portion, and has a double layer structure. The height difference between the black matrix and the color filter is increased by the transparent resin, and then, based on the increased height difference, a photoresist portion of the planarizing layer is formed by means of gray tone exposure and development so as to minimize the height difference. In this manner, a layer thickness of the photoresist portion is precisely controlled. Thus, the technical problem such as product yield decrease and low display quality due to t the height difference between the color filter and the black matrix of the display substrate is avoided.

### Fourth Embodiment

The fourth embodiment of the disclosure provides a display device which comprises a display substrate according to the first embodiment, the second embodiment and the third embodiment, and other structures of the display device are the same as conventional ones, and will not be repeated herein.

The display device according to the embodiment can be a liquid crystal panel, a liquid crystal display device, a liquid crystal TV, an organic light-emitting diode (OLED) display panel, an OLED TV, a cell phone, a palm computer, a digital photo frame and the like.

In the display substrate comprised in the display device according to the embodiment, a planarizing layer is formed on the black matrix or on both the black matrix and the color filter so as to planarize the height difference between the black matrix and the color filter. The planarizing layer can minimize the height difference between the black matrix and the color filter and effectively improve the surface smoothness of the color filter. Thus, the product yield is increased and the display quality is improved.

### Fifth Embodiment

The fifth embodiment of the disclosure provides a method of manufacturing a display substrate. The method comprises the following steps: Step S101, providing a base substrate; Step S102, forming a black matrix and a color filter on the base substrate; and Step S103, forming a planarizing layer on the base substrate on which the black matrix and the color filter are formed.

In one implementation, in the step S103 of the embodiment, a planarizing layer for planarizing a height difference between the black matrix and the color filter is formed on the black matrix. The planarizing layer has an upper surface flushed with an upper surface of the color filter so as to minimize the height difference between the black matrix and the color filter.

In another implementation, in the step S103 of the embodiment, a planarizing layer for planarizing the height difference between the black matrix and the color filter is formed on both the black matrix and the color filter, and a portion of the planarizing layer corresponding to the black matrix and a portion of the planarizing layer corresponding to the color filter have different layer thicknesses. In such a case, the upper surface of the planarizing layer disposed on the black matrix and the color filter is a plane, and can minimize the height difference between the black matrix and the color filter.

In the embodiment, after forming a black matrix and a color filter on the base substrate, the method further comprises a step of forming a planarizing layer on the black matrix or on both the black matrix and the color filter. The planarizing layer is configured for planarizing the height difference between the black matrix and the color filter. The planarizing layer can improve surface smoothness of the color filter effectively. Thus, the product yield is increased and the display quality is improved.

### Sixth Embodiment

In the sixth embodiment, a photoresist is used to form a planarizing layer on the black matrix or on both the black matrix and the color filter by means of lithography during manufacturing a display substrate, so as to improve surface smoothness of the color filter and improving image displaying quality. Here, only the difference between this embodiment and the fifth embodiment will be specifically described and the common features between the present embodiment and the fifth embodiment will be omitted.

In the present embodiment, a photoresist is adopted to form the planarizing layer and the adopted photoresist is a transparent photoresist or an opaque photoresist. For example, the step S103 for forming the planarizing layer comprises the following steps.

Step S103a, a photoresist is formed on the base substrate on which the black matrix and the color filter formed.

For example, in the embodiment, the photoresist can be formed on the black matrix and the color filter by methods such as coating, deposition and the like.

Step S103b, the photoresist formed in the step S103a is exposed by means of a gray tone mask according to the height difference between the black matrix and the color filter.

For example, different degrees of exposure will have different development result for the photoresist during the development. Thus, in order to minimize the height difference between the black matrix and the color filter, the photoresist on the black matrix and the photoresist on the color filter are exposed differently using a gray tone mask according to the height difference between the black matrix and the color filter, such that the photoresist on the black matrix and the photoresist on the color filter are dissolved differently in the development. Thus, the remaining photoresist after dissolution minimizes the height difference between the black matrix and the color filter as illustrated in FIG. 1.

Step S103c, the photoresist exposed in the step S103b is developed, and a first photoresist region and a second photoresist are formed.

For example, the color filter is higher than the black matrix in the embodiment. In order to avoid affecting the transmissivity of the display panel, the photoresist at regions corresponding to the color filter on the base substrate is completely removed and the photoresist at regions corresponding to the black matrix on the base substrate remains completely or partially.

Further, the photoresist exposed in the step S103b is developed so as to form a first photoresist region corresponding to the color filter and a second photoresist region corresponding to the black matrix. The photoresist in the first photoresist region is removed completely, and the photoresist in the second photoresist region remains completely or partially, and the upper surface of the second photoresist region is flushed with the upper surface of the color filter. Thus, the completely or partially remaining photoresist in the second photoresist region corresponding to the black matrix is used to minimize the height difference between the black matrix and the color filter. Therefore, the product yield is increased and the image display quality is improved.

In the method for manufacturing a display substrate according to the embodiment, according to the height difference between the black matrix and the color filter, the photoresist on the color filter is completely removed and the photoresist corresponding to the black matrix remains completely or partially by a lithography process with a gray tone mask. The completely or partially remaining photoresist corresponding to the black matrix minimizes the height difference between matrix and the color filter. Thus, the product yield is increased and the image display quality is improved.

### Seventh Embodiment

A transparent photoresist is adopted for making a planarizing layer in this embodiment, and the step S103a for forming a planarizing layer comprises the following steps, for example.

Step S103d, a transparent photoresist is formed on the base substrate on which the black matrix and the color filter formed.

In this embodiment, a transparent photoresist is formed on the base substrate on which the black matrix and the color filter formed by means of a coating, deposition and the like.

Step S103e, according to the height difference between the black matrix and the color filter, the transparent photoresist formed in the step S103d is exposed with a gray tone mask.

Step S103f, the photoresist exposed in the step S103e is developed so as to form a third photoresist region and a fourth photoresist region.

For example, in the embodiment, the photoresist in third photoresist region corresponding to the black matrix region remains completely or partially, and the photoresist in the fourth photoresist region corresponding to the color filter region remains partially, and the upper surface of the third photoresist region corresponding to the black matrix region is flushed with the fourth photoresist region corresponding to the color filter region.

In the embodiment, as the photoresist corresponding to the black matrix region and corresponding to the color filter region is not completely removed in subsequent processes, the photoresist can be cured, and then the cured photoresist is mechanically polished such that the upper surface of the photoresist corresponding to the black matrix region is flushed with the upper surface of the photoresist corresponding to the color filter region.

In the method of manufacturing a display substrate according to the embodiment, according to the height difference between the black matrix and the color filter, a portion of the transparent photoresist on the color filter remains and a portion of the transparent photoresist on the black matrix remains completely or partially by a lithography process with a gray tone mask, such that the upper surface of the third photoresist region corresponding to the black matrix region is flushed with the upper surface of the fourth photoresist region corresponding to the color filter region, so as to minimize the height difference between the black matrix and the color filter. Thus, the product yield is increased and the image display quality is improved.

### Eighth Embodiment

The eighth embodiment of the disclosure further provides a method of manufacturing a display substrate. Here, only difference between the eighth embodiment and the fifth embodiment is specifically described and the common features is omitted. The step S103 for forming a planarizing layer comprises following steps for example.

Step S103g, a transparent resin is formed on the base substrate on which the black matrix and the color filter are formed.

For example, in the eighth embodiment, a transparent resin is formed on the base substrate formed with the black matrix and the color filter by means of coating, deposition and the like. The transparent resin can be an organic resin, an inorganic resin, or any other material capable of achieving objects of the embodiment of the disclosure.

In the eighth embodiment, after the transparent resin is formed on the black matrix and the color filter, a portion of the surface of the resultant transparent resin corresponding to the regions of the black matrix and of the color filter having a height difference is not smooth either, due to the height difference between the black matrix and the color filter. That is to say, there is a height difference between the transparent resin at regions corresponding to the black matrix region and the transparent resin at regions corresponding to the color filter region. And further, as the transparent resin is formed on both the black matrix and the color filter, the height difference between the black matrix and the color filter is further increased by the transparent resin.

Step S103h, a photoresist is formed on the transparent resin.

For example, in the eighth embodiment, the photoresist formed on the transparent resin can be a positive photoresist or a negative photoresist. And moreover, the photoresist can be a transparent photoresist or an opaque photoresist.

Step S103i, based on the height difference between the transparent resin corresponding to the black matrix region and the transparent resin corresponding to the color filter region, the photoresist coated in step S103h is exposed in different degrees with a gray tone mask and developed, thus, a fifth photoresist region corresponding to the color region and a sixth photoresist region corresponding to the black matrix region are formed.

In the eighth embodiment, the photoresist in the fifth photoresist region corresponding to the color region is completely removed, and the photoresist in the sixth photoresist region corresponding to the black matrix region remains partially or completely. The upper surface of the sixth photoresist region corresponding to the black matrix region is flushed with the upper surface of the transparent resin corresponding to the color filter.

It should be noted that, it is not necessary to completely remove the photoresist corresponding to the color filter region if the photoresist used in the embodiments of the disclosure does not effect the transmissivity of the display panel, and the photoresist can remain as long as the upper surface of the photoresist eventually formed corresponding to the black matrix region is in a same plane as the upper surface of the photoresist formed corresponding to the color filter region. That is to say, a portion of the photoresist in the fifth photoresist region corresponding to the color filter region partially remains and a portion of the photoresist in the sixth photoresist region corresponding to the black matrix remains partially or completely, the upper surface of the sixth photoresist region corresponding to the black matrix is in a same plane as the upper surface of the fifth photoresist region corresponding to the color filter region.

In embodiments of the present disclosure, a layer of transparent resin is formed on the black matrix and the color filter in advance, a corresponding height difference is generated between the transparent resin corresponding to the black matrix region and the transparent resin corresponding to the color filter, and this height difference is increased with respect to the height difference between the black matrix and the color filter. The photoresist in various regions are exposed in different degrees and developed, and thus layer thicknesses of the photoresist can be accurately controlled. Therefore, the product yield is increased and the image displaying quality is improved.

The photoresist used in the sixth to the eighth embodiment of the disclosure can be a positive photoresist or a negative photoresist. The photoresist is exposed in different ways depending on the properties of the photoresist. For example, when a negative photoresist is used, if a photoresist completely remaining region needs to be formed, the photoresist in the corresponding region is completely exposed; if a photoresist partially remaining region needs to be formed, the photoresist in the corresponding region is partially exposed; and if a photoresist completely removed region needs to be formed, the photoresist in the corresponding region is not exposed. If a positive photoresist is used, it should be exposed in contrary manners.

The above description is merely exemplary embodiments of the invention, but are not used to limit the protection scope of the invention. The protection scope of the invention shall be defined by the attached claims.

1. A display substrate comprising:
a base substrate,
a black matrix and a color filter formed on the base substrate, the color filter and the black matrix arranged alternately with a height difference between the black matrix and the color filter,
wherein the display substrate further comprising a planarizing layer configured to minimize the height difference between the black matrix and the color filter.

2. The display substrate according to claim 1, wherein the planarizing layer is made of a photoresist.

3. The display substrate according to claim 2, wherein the photoresist is an opaque photoresist, and the opaque photoresist is formed on the black matrix and have an upper surface flushed with an upper surface of the color filter.

4. The display substrate according to claim 2, wherein the photoresist is a transparent photoresist, and the transparent photoresist is formed on the black matrix and have an upper surface of the transparent photoresist flushed with an upper surface of the color filter; or
the transparent photoresist is formed on both the black matrix and the color filter, and have a planar upper surface.

5. The display substrate according to claim 1, wherein the planarizing layer comprises a transparent resin and a photoresist, the transparent resin covers both the black matrix and the color filter, the photoresist covers the transparent resin corresponding to the black matrix, and the photoresist have an upper surface flushed with an upper surface of the transparent corresponding to the color filter.

6. The display substrate according to claim 1, wherein the planarizing layer is made of a transparent resin, and the planarizing layer is disposed on the black matrix or on both the black matrix and the color filter.

7. A display device comprising the display substrate according to claim 1.

8. A method of manufacturing a display substrate, comprising following steps of:
forming a black matrix and a color filter on a base substrate,
forming a planarizing layer on the base substrate on which the black matrix and the color filter are formed, the planarizing layer configured to minimize a height difference between the black matrix and the color filter formed.

9. The method according to claim 8, wherein the planarizing layer is made of a photoresist, the step of forming a planarizing layer on the base substrate on which the black matrix and the color filter are formed comprises following steps of:
forming a photoresist on the base substrate on which the black matrix and the color filter are formed;
depending on the height difference between the black matrix and the color filter, exposing and developing the photoresist with a gray tone mask, so as to form a first photoresist region corresponding to the color filter region and a second photoresist region corresponding to the black matrix region;
wherein the photoresist in the first photoresist region is completely removed, the photoresist in the second photoresist region partially or completely remains, such that an upper surface of the second photoresist region is flushed with an upper surface of the color filter.

10. The method according to claim 8, wherein the planarizing layer is made of a transparent photoresist, the step of forming a planarizing layer on the base substrate on which the black matrix and the color filter are formed comprises following steps of:
forming a photoresist on the base substrate on which the black matrix and the color filter are formed;
depending on the height difference between the black matrix and the color filter, exposing and developing the photoresist with a gray tone mask so as to form a third photoresist region corresponding to the black matrix region and a fourth photoresist region corresponding to the color filter region;
wherein the photoresist in the third photoresist region completely or partially remains, the photoresist in the fourth photoresist region partially remains, and an upper surface of the third photoresist region is flushed with an upper surface of the fourth photoresist region.

11. The method according to claim 8, wherein the planarizing layer is made of a transparent resin and a photoresist; the step of forming a planarizing layer on the base substrate on which the black matrix and the color filter are formed comprises:
forming a transparent resin on the base substrate on which the black matrix and the color filter are formed;
forming a photoresist on the transparent resin;
depending on the height difference between the black matrix and the color filter, exposing and developing the photoresist with a gray tone mask so as to form a fifth photoresist region corresponding to the color filter region and a sixth photoresist region corresponding to the black matrix region;
wherein the photoresist in the fifth photoresist region is completely removed, the photoresist in the sixth photoresist region partially or completely remains, an upper surface of the sixth photoresist region corresponding to the black matrix region is flushed with an upper surface of the transparent resin corresponding to the color filter.
